(19) United States
(12) Patent Application Publication
(10) Pub. No.: US 2025/0255009 A1
(43) Pub. Date: Aug. 7, 2025

(54) SEMICONDUCTOR CIRCUIT WITH A SEMICONDUCTOR DEVICE

(71) Applicant: Infineon Technologies Austria AG, Villach (AT)

(72) Inventors: Christian Ranacher, Gaimberg (AT); Oliver Blank, Villach (AT); Alessandro Ferrara, Villach (AT); Maximilian Rösch, St. Magdalen (AT)

(21) Appl. No.: 19/021,528

(22) Filed: Jan. 15, 2025

(30) Foreign Application Priority Data
Feb. 2, 2024 (DE) 102024102997.8

(51) Int. Cl. H10D 89/60; H10D 30/01; H10D 30/66; H10D 64/00

(52) U.S. Cl. CPC H10D 89/813; H10D 30/0291; H10D 64/115; H10D 64/117; H10D 89/611; H10D 30/668

(57) ABSTRACT

The present application relates to a semiconductor circuit, including a semiconductor device and a delay element. The semiconductor device includes a gate electrode and a field electrode in a field electrode trench. The delay element is electrically connected between the gate electrode and the field electrode. The delay element is configured to delay a charging of the field electrode compared to a charging of the gate electrode. A semiconductor die that includes the semiconductor circuit and a method of manufacturing the semiconductor die are also described.

### TECHNICAL FIELD

The present application relates to a semiconductor circuit with a semiconductor device.

### BACKGROUND

Semiconductor devices typically include a gate region, e.g. to control a current flow in a channel. Additionally, some semiconductor device may include a field electrode arranged in a field electrode trench.

### SUMMARY

It is an object of the present application to provide an advantageous semiconductor circuit with a semiconductor device.

In an embodiment, the semiconductor circuit comprises a delay element which is electrically connected between the gate electrode and the field electrode of the semiconductor device. With the delay element, a charging of the field electrode may be coupled but be delayed compared to a charging of the gate electrode. In other words, the field electrode is connected but not tied directly to the gate electrode. The delay element in between may delay the charging of the field electrode, for instance until the gate electrode has charged.

Connecting the field electrode to the gate electrode, e.g. applying the gate voltage to the field electrode, can for instance reduce the Ron of the device, the gate potential at the field electrode may improve a conduction path through the semiconductor body. In comparison to biasing the field electrode directly with the gate potential, the delay element may be advantageous as to a switching behavior, for example in dynamic switching applications. The delayed charging of the field electrode, for instance until the drain voltage has dropped and the gate voltage has passed the Miller-Plateau, may reduce switching losses, e.g. improves dynamic parameters, the delay can for example circumvent a gate to drain capacitance (CGD) contribution of the field electrode.

Particular embodiments and features are presented throughout this disclosure. Thereby, the individual features shall be disclosed independently of a specific claim category, the disclosure relates to apparatus and device aspects, but also to method and use aspects. In particular, it relates to the semiconductor circuit as such and to a semiconductor die in which a respective circuit is integrated. In general words, an approach of this application is to connect a gate and field electrode of a device via a delay element, the field electrode being in particular arranged in a trench.

As detailed below, the gate and field electrode can be stacked above each other in the same field electrode trench. Alternatively, the gate electrode may be arranged outside the field electrode trench, for example in case of a planar gate on a first side (frontside) of a semiconductor body or in a separate gate trench laterally aside the field electrode trench. The field electrode trench extending vertically into the semiconductor body may have a needle shape (e.g. columnar shape) or an elongated extension in a lateral direction, for instance as a stripe in a cell field with a plurality of parallel stripes.

The semiconductor body may comprise a semiconductor substrate and for instance one or several epitaxial layers on the substrate. In the semiconductor body, load terminals of the device may be formed, for instance a source region, a body region and a drain region in case of a FET. The field electrode in the trench may improve a conduction in the semiconductor body, for instance in a drift region of the device, into which the field electrode trench extends. The drift region, which may be part of a FET or, alternatively, of an IGBT, can particularly be formed in an epitaxial layer, the field electrode improving a conductance in the epitaxial layer or layer system.

Basically, the delay element may be a switch, for instance a transistor, which provides for the delayed connection of the field electrode to the gate electrode. In a particular embodiment, the delay element is a resistor connecting the field electrode to the gate electrode. The resistor may have a resistance of at least 1 Ω/mm² device area, further lower limits being for example 5Ω, 10Ω, 20Ω, 30Ω, 40Ω or 50Ω, respectively per mm² device area. In detail, the resistance may for instance be chosen depending on the device characteristics and/or switching requirements in the application. By way of example, a possible upper limit of the resistance can be 500 Ω/mm² device area. In general, the delay element, in particular resistor, may in addition to the charging of the field electrode also be used for discharging it subsequently.

In an embodiment, the circuit additionally comprises a discharge element, e.g. separate from the delay element, connected to the field electrode. The discharge element may be configured to discharge the field electrode when the gate electrode is discharged, it may for instance be implemented as a diode connected between the gate electrode and the field electrode, for example in parallel to the delay element/resistor. The diode may block a charging of the field electrode from the gate electrode, so that the charging is done via the delay element, but may allow for a discharging of the field electrode to the gate electrode, for instance via the gate electrode to a ground domain. In the exemplary embodiments, a cathode contact of the diode is connected to the gate electrode and an anode contact of the diode is connected to the field electrode.

In an embodiment, the discharge element is a discharge transistor. The discharge transistor may be connected between the field electrode and a ground domain, for instance between the field electrode and a ground/source pad when the device and the discharge transistor are integrated in the same die (see in detail below). Independently of integration details, the discharge transistor can connect the field electrode to the ground domain in a conducting state. In other words, it can be considered as a pull-down device that pulls down the field electrode. In general, the discharge transistor may for instance be driven externally.

In an embodiment, a control terminal of the discharge transistor is coupled to a drain domain of the semiconductor device via a resistive and/or capacitive voltage divider. With the voltage divider for instance an increasing source to drain potential can be sensed, e.g. resulting from the transistor device (main device) being switched off. The potential rise sensed with the voltage divider may be transferred to the control terminal, e.g. trigger the discharge transistor to discharge the field electrode. In general, a bipolar discharge transistor is conceivable, in the exemplary embodiments a FET is provided.

In an embodiment, the circuit additionally comprises a capacitor connected between the field electrode and a ground domain. In other words, a first capacitor electrode of the capacitor connects to the field electrode, for instance is connected between the field electrode and the resistor (delay element), and a second capacitor electrode of the capacitor connects to the ground domain. In case of a capacitor integrated with the device in the same die (see below), the capacitor may for instance connect to a ground pad that can in particular be a source pad of the die. Independently of integration details, e.g. also in case of an external set up, the capacitor may keep the field electrode potential low during switching events, for example when the resistor (delay element) is also used as discharge element, see the remarks above.

In an embodiment, a semiconductor die is provided, which may comprise a semiconductor body and a wiring structure. The semiconductor device may be formed in the semiconductor die, the field electrode trench with the field electrode arranged for instance in the semiconductor body, see in detail above. In addition, the die may comprise the delay element connected between the gate electrode and the field electrode of the device. The wiring structure on the semiconductor body, for instance on a first side of the semiconductor body, may comprise a metallization layer, e.g. a single layer or a stack with a plurality of metallization layers, and may for instance be used for connecting the delay element to the gate electrode and/or connecting the delay element to the field electrode.

Any circuit disclosed here may be integrated in a common semiconductor die. As to a possible setup of the semiconductor device, e.g. arrangement/design of the gate and/or field electrode, reference is made to the introductory remarks above. For instance, the semiconductor device may have a first load terminal at the first side of the semiconductor body and a second load terminal at a vertically opposite second side of the semiconductor body, the first load terminal being for instance a source region and the second load terminal a drain region. The field electrode trench may extend from the first side into the semiconductor body. In particular embodiments, the gate electrode and the field electrode are arranged in the same field electrode trench, in particular the gate electrode stacked above the field electrode.

In an embodiment, the discharge element, in particular discharge transistor, is integrated in the die. In the semiconductor body, a respective device structure of the semiconductor device and of the discharge transistor may be formed, for instance laterally aside each other. The semiconductor device and the discharge transistor may, at least partly, have doped regions and/or trenches/electrodes formed in the same layers, e.g. be at least to some extent manufactured simultaneously.

In between the devices, an isolation may be formed, for example a junction isolation or deep trench isolation. A deep trench can for instance intersect the semiconductor body completely, e.g. extend between the first side and the second side of the semiconductor body when viewed in a vertical cross-section. Likewise, for instance a different electrical potential can be applied, e.g. at the second side of the semiconductor body, for example a drain potential for the semiconductor device and a source and/or ground potential for the discharge transistor.

In general, the discharge transistor may be a lateral device, e.g. having its load terminals, for instance source and drain region, at the same side of the semiconductor body. This may be combined with a planar gate on the semiconductor body but also with a gate electrode in a trench, the lateral channel arranged aside the trench.

In a particular embodiment, the discharge transistor is a vertical device having its source region and drain region at opposite sides of the semiconductor body. In particular, the source region of the discharge transistor may be arranged at the first side of the semiconductor body, for instance connected to a source and/or ground pad of the semiconductor device. The drain region of the discharge transistor, which may be arranged at the vertically opposite second side of the semiconductor body, can be connected to the field electrode of the semiconductor device.

In a particular embodiment, a deep contact structure, which extends from the first side into the semiconductor body, is connected to the drain region of the discharge transistor. In other words, the deep contact structure reaches into the semiconductor body to connect the second side of the discharge transistor to the first side of the semiconductor device, e.g. to provide for a vertical current routing between the frontside and backside. The deep contact structure may comprise a trench and/or implant structure, in particular a sinker implant and contact plug connecting the sinker implant to the first side. Referring to a gate and/or field electrode trench of the discharge transistor, a lower end of the deep contact structure may be arranged at a greater vertical depth than a lower end of this gate and/or field electrode trench (e.g. be arranged at a larger vertical distance from the first side of the semiconductor body).

In an embodiment, the wiring structure of the die comprises a conductor line which connects the field electrode of the semiconductor device to the drain region of the discharge transistor. The conductor line may in particular extend across an isolation, for instance deep trench isolation (see above), between the semiconductor device and the discharge transistor. In case of the drain region of the discharge transistor connected via a deep contact structure discussed above, the conductor line may be connected to the deep contact structure.

Generally, the device can comprise a plurality of device cells, the device cells connected for instance in parallel. A respective cell layout may also depend from the device design/type, a matrix-like device cell arrangement, e.g. in a quadratic or honeycomb lattice, applied for instance in case of a needle-shaped field electrode trench discussed above. In case of a field electrode trench with an elongated extension in a lateral direction (“length direction”), a plurality of stripe-shaped device cells may be arranged aside each other in a transverse direction (e.g. perpendicularly to the length direction). The conductor line may extend across a plurality of device cells, each having a field electrode, and be connected to each of these field electrodes. In case of elongated field electrodes, e.g. “field plates”, the conductor line or “field plate finger” may extend across the plurality of elongated trenches, e.g. in the transverse direction, and be connected to the respective field plates.

In an embodiment, the semiconductor die comprises a capacitor coupling the control terminal of the discharge transistor to the drain domain of the semiconductor device, see above. A first capacitor electrode connected to the drain domain may in particular be arranged in a trench, the trench extending for instance from the first side into the semiconductor body and having for example the same depth like the field electrode trench of the semiconductor device. The first capacitor electrode may be made in the same layer, e.g. in the same process step, or of the same material like the field electrode and/or a gate electrode of the semiconductor device.

A second capacitor electrode of the capacitor coupling the control terminal to the drain region of the semiconductor device may be formed in the semiconductor body, it may for instance enclose the trench with the first capacitor electrode laterally and/or vertically downwards. A dielectric of the capacitor, which is arranged between the first and the second capacitor electrode, may be formed at the bottom and/or side wall of the trench, for instance of the same material/in the same process steps like a dielectric in the field electrode trench of the semiconductor device.

In an embodiment, a resistive element of the resistor (delay element) is made of polysilicon in a trench. It can in particular be formed in the same polysilicon layer like the gate electrode of the semiconductor device. The resistance of the resistor may be primarily determined by the resistance of the resistive element, another contribution may for instance come from contact plugs or the like.

In an embodiment relating to the capacitor connected between the field electrode and a ground domain (see above), a capacitor electrode of this capacitor is arranged in a trench. It may in particular be arranged above the field electrode of the semiconductor device in the same die, e.g. in a portion of the longitudinal/elongated trench, in which portion the gate electrode is interrupted. In other words, it may be arranged in the same layer with the gate electrode of the semiconductor device, for instance also in the same layer with the resistor integrated into the trench (see above). In still other words, the same trench may comprise the gate electrode in an active area and the capacitor electrode and/or resistor outside the active area, e.g. aside the gate electrode in the same trench but isolated therefrom.

In an embodiment relating to the discharge element being a diode, the diode is made of polysilicon. In a respective polysilicon layer, a first and second doping type region adjacent each other may form the diode. In particular, the polysilicon diode can be arranged in a trench, for instance formed in the same polysilicon layer like the gate electrode of the semiconductor device and/or resistor (delay element).

In an embodiment, a semiconductor device/die is provided, which comprises: a gate electrode; a field electrode disposed in a trench; a resistor electrically connected between the gate electrode and the field electrode; and a discharge element electrically connected between the field electrode and a ground domain, wherein the discharge element is one of a discharge transistor, a diode and a resistor.

An embodiment relates to a method of manufacturing a semiconductor die, comprising the steps: forming the semiconductor device; and forming the delay element.

As discussed above, these steps may, at least partly, be integrated, namely comprise simultaneous process steps.

### BRIEF DESCRIPTION OF THE DRAWINGS

Below, the semiconductor circuit and die, as well as the manufacturing, are explained in further detail by means of exemplary embodiments. Therein, the individual features can also be relevant in a different combination.

FIG. 1 shows a schematic cross-section of a semiconductor device with a field electrode trench and illustrates a connection between a gate electrode and a field electrode schematically;

FIG. 2 illustrates in further detail the wiring of the gate electrode and the field electrode in a first semiconductor circuit;

FIG. 3 shows a cross-sectional view of a semiconductor die and illustrates connection details of the first semiconductor circuit;

FIG. 4 shows the semiconductor die of FIG. 3 in a top view;

FIG. 5a shows another cross-sectional view of the semiconductor die and illustrates further connection details of the first semiconductor circuit;

FIG. 5b shows another cross-sectional view of the semiconductor die and illustrates further connection details of the first semiconductor circuit;

FIG. 6 shows a wiring of the gate electrode and field electrode in a second semiconductor circuit;

FIG. 7a shows a cross-sectional view of a semiconductor die and illustrates some connection details of the second semiconductor circuit;

FIG. 7b shows the same cross-sectioned view like FIG. 7a and illustrates a slightly modified contact structure;

FIG. 8 shows a wiring of the gate electrode and field electrode in a third semiconductor circuit;

FIG. 9 shows a cross-sectional view of a semiconductor die and illustrates some connection details of the third semiconductor circuit; and

FIG. 10 summarizes some manufacturing steps in a flow diagram.

### DETAILED DESCRIPTION

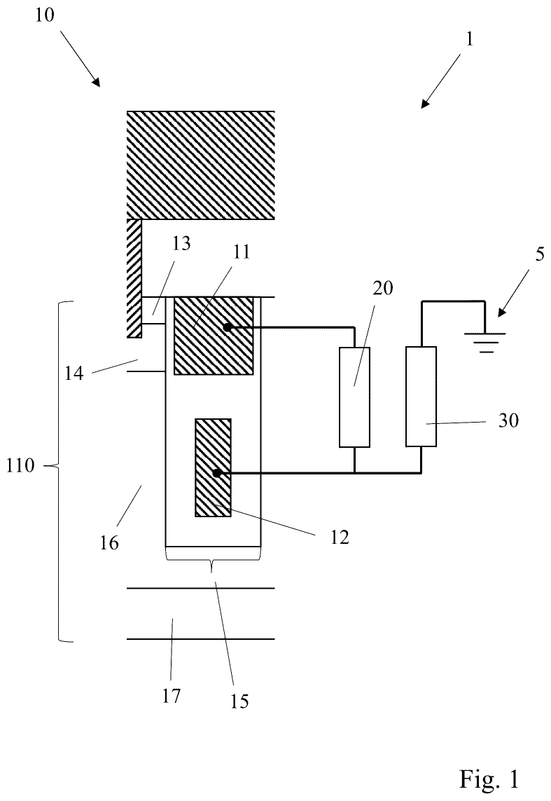

FIG. 1 shows a cross-sectional view of a semiconductor device 10 which is part of a semiconductor circuit 1. The semiconductor device 10 comprises a source region 13, a body region 14, a drift region 16 and a drain region 17, each formed in a semiconductor body 110. In the example shown, the source region 13, the drift region 16 and the drain region 17 are n-doped, the drift region 16 with a lower doping concentration compared to the drain region 17. The body region 14 is p-doped, wherein a gate electrode 11 is arranged laterally aside the body region 14. The device 10 further comprises a field electrode 12 disposed in a field electrode trench 15 which extends into the drift region 16. In the example shown, the gate electrode 11 is stacked above the field electrode 12 in the same field electrode trench 15. However, as discussed above, the field electrode 12 could also be combined with a gate electrode outside the field electrode trench 15, for instance a planar gate on a first side 110.1 of the semiconductor body 110 or a gate electrode in a separate gate trench.

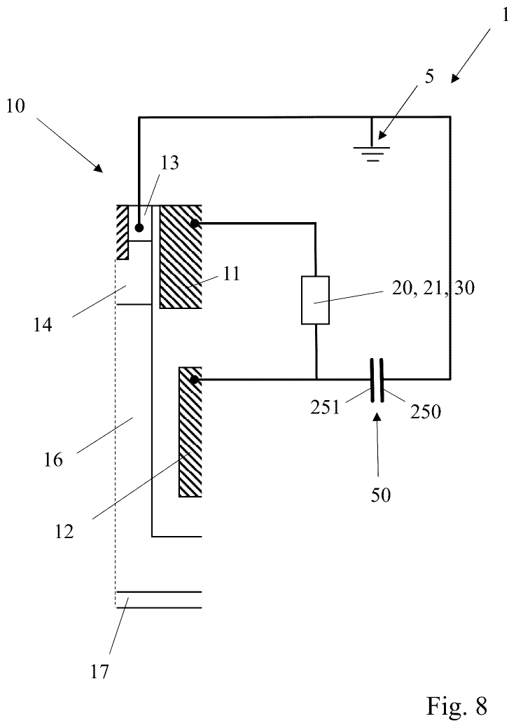

In the semiconductor circuit 1, the field electrode 12 is connected to the gate electrode 11 via a delay element 20. With the delay element 20, a gate potential is applied to the field electrode 12 with a delay, e.g. once the gate electrode 11 has charged, e.g. at least past the Miller plateau. In general, the delay element 20 can also serve for discharging the field electrode later, see FIG. 8 in detail. In the embodiment of FIG. 1, an additional discharge element 30 is provided. It connects the field electrode 12 to a ground domain 5, e.g. for discharging the field electrode 12 after a switching event.

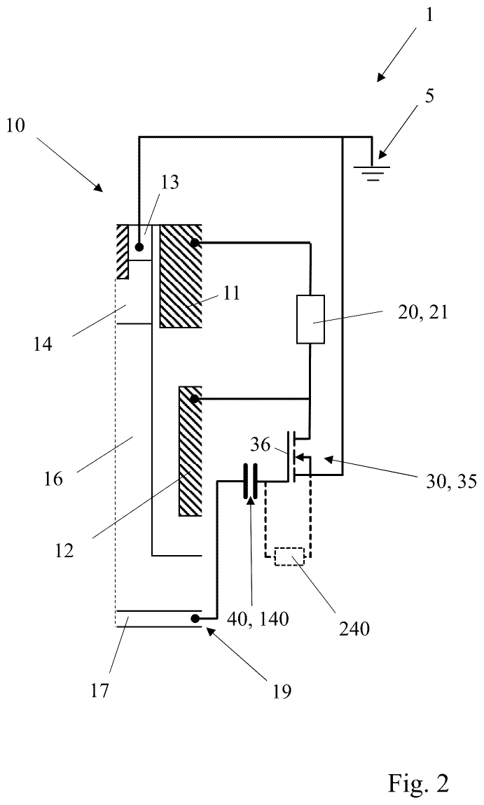

FIG. 2 illustrates a first embodiment of the semiconductor circuit 1 in further detail, for the same device 10 as described above (shown only partly in FIG. 2). Generally, in this disclosure, the like reference numeral indicates the like part or parts having the like function, and reference is made to the description of the respectively other figures as well. The delay element 20 of FIG. 2 is a resistor 21, in the example shown with a resistance of around 20 Ω/mm² device area. In general, the resistance could be more or less, depending on circumstances (as also described further above).

The discharge element 30 is a discharge transistor 35, which in a conducting state connects the field electrode 12 to the ground domain 5. A control terminal 36 of the discharge transistor 35 is coupled to a drain domain 19, namely a drain region 17 of the semiconductor device 10, via a voltage divider 40. In the embodiment of FIG. 2, the voltage divider 40 comprises a capacitor 140 connected between the drain domain 19 and the control terminal 36. A resistor 240 shown in dashed lines may optionally be provided for charging a gate-to-source capacitance of the discharge transistor 35 or for a discharging of the capacitor 40.

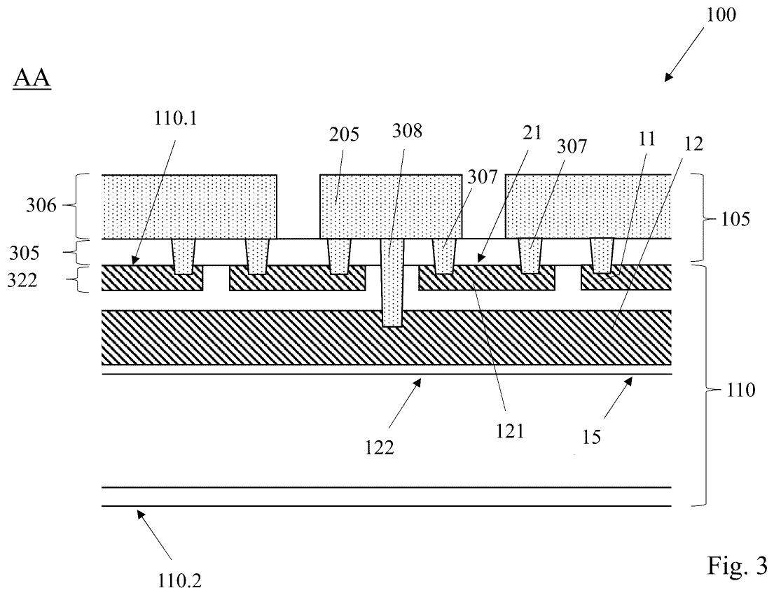

FIG. 3 shows a cross-sectional view through a portion of a semiconductor die 100 and illustrates an integration of elements of the circuit 1 of FIG. 2. In the semiconductor body 110, a trench 122 is provided, which has an elongated extension in the drawing plane. In the trench 122, a resistive element 121 of the resistor 21 is arranged, wherein the resistive element 121 is made of polysilicon. In this example, the trench 122 with the resistive element 121 is a lateral portion of the field electrode trench 15, which in another portion comprises the gate electrode 11 and the field electrode 12. The gate electrode 11 and the resistive element 121 are made in the same polysilicon layer 322, e.g. can be manufactured in the same process steps. In FIG. 3, the actual device cells with the respective transistor structure are arranged in front of and behind the drawing plane.

On the semiconductor body 110, a wiring structure 105 is arranged, which comprises an insulation layer 305 and a metallization layer 306, as well as several vertical interconnects 307. In the metallization layer 306, a conductor line 205 is formed, it connects the resistor 21, in particular resistive element 121, to the field electrode 12. In FIG. 3, a symmetric setup is shown, the conductor line extending through the cell field, e.g. perpendicular to the drawing plane, with an active transistor structure arranged on both sides of conductor line 205. Alternatively, the conductor line 205 may extend aside the active area, e.g. be arranged between the active area and an edge termination structure (not shown here).

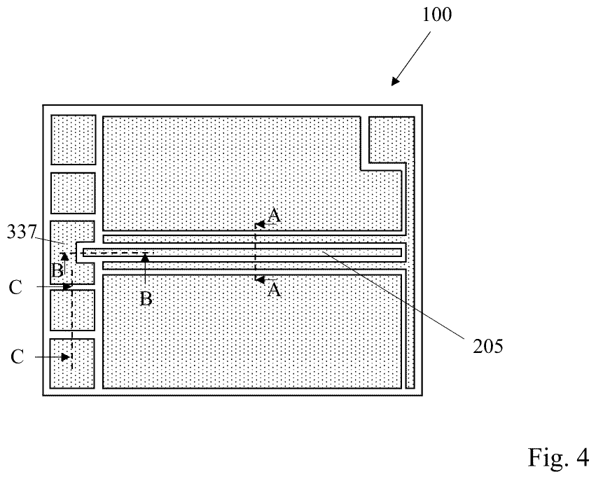

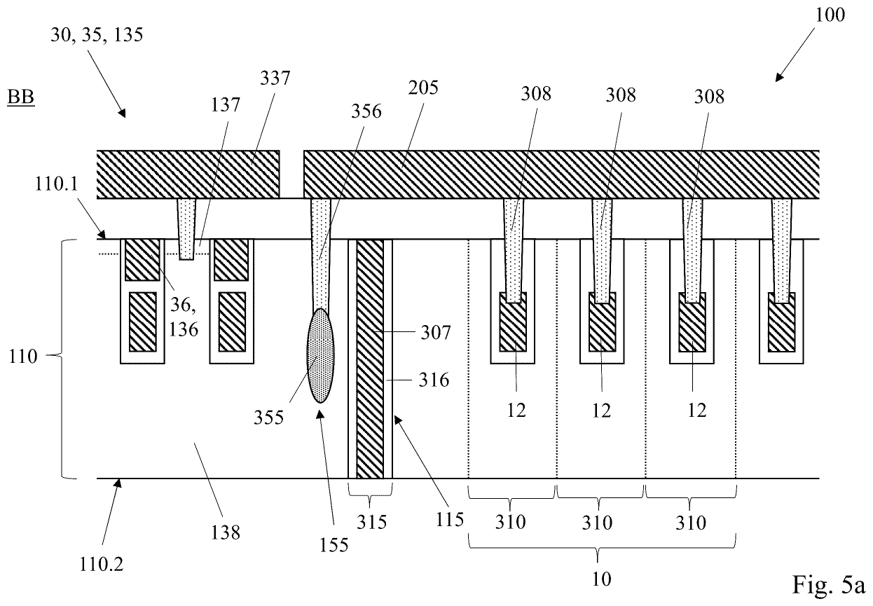

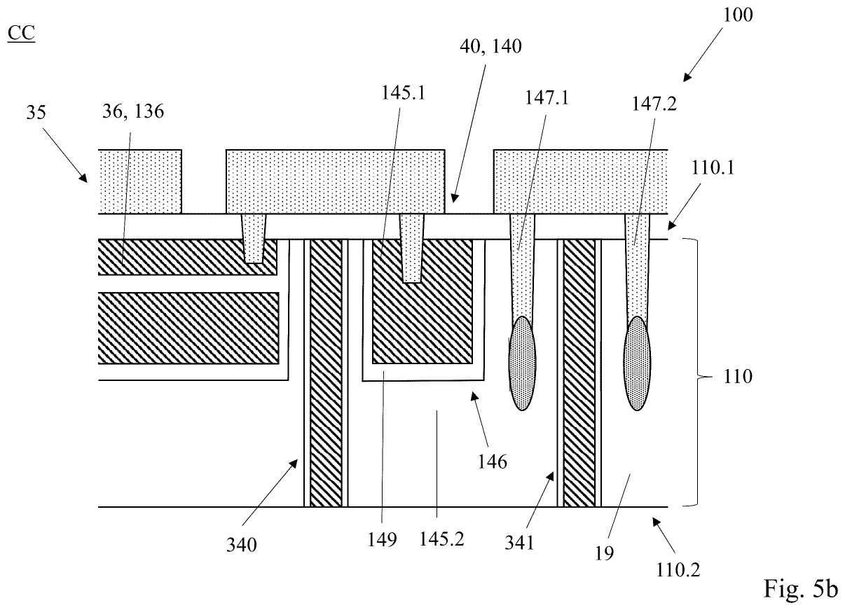

FIG. 4 shows the semiconductor die 100 of FIG. 3 in a schematic top view, namely looking vertically onto the frontside of the die 100. The sectional plane AA of FIG. 3 lies perpendicular to a length extension of the conductor line 205, as indicated in FIG. 4. Further, two more sectional planes are referenced in FIG. 4, wherein the sectional plane BB illustrates the connection of the conductor line 205 to the drain region of the discharge element (see FIG. 5a) and the sectional plane CC illustrates the capacitive coupling of a gate electrode of the discharge transistor to the drain domain (see FIG. 5b in detail).

FIG. 5a shows another cross-sectional view of the die 100 with the circuit 1 shown in FIG. 2, wherein the sectional plane BB lies perpendicular to the drawing plane of FIG. 3. It illustrates the length extension of the conductor line 205 which extends along a plurality of device cells 310. In FIG. 5a, a respective field electrode connection of the conductor line 205 is shown, see the vertical interconnects 308. In addition to connecting the field electrode 12 to the resistor 21, the conductor line 205 connects the field electrode 12 of a respective device cell 310 to the discharge element 30, namely discharge transistor 35 in the embodiment of FIG. 5a. In detail, the conductor line 205 connects the field electrode(s) to a drain region 138 of the discharge transistor 35, see also the circuit diagram of FIG. 2 for illustration.

In the embodiment of FIG. 5a, the discharge transistor 35 is a vertical device 135, having its source region 137 and drain region 138 on opposite sides 110.1, 110.2 of the semiconductor 110. The discharge transistor 35 and the semiconductor device 10 are electrically isolated from each other by a deep trench isolation 115 comprising a deep trench 315 which intersects the semiconductor body 110. In the example shown, the deep trench 315 is filled with an insulating material 316 and an inlay 307, for instance made of polysilicon.

The conductor line 205 extends across the deep trench isolation 115 and is connected to the drain region 138 via a deep contact structure 155. In the example shown, the deep contact structure 155 comprises a sinker implant 355, which can provide for a low ohmic contact to the drain region 138, and a contact plug 356 extending down to the sinker implant 355. The contact plug 356 can be made like the contacts 308, in particular in the same process steps. The source region 137 of the discharge transistor 35 is connected to a source plate 337 formed in the metallization layer 306, namely to the source region of the device and ground domain 5, thus.

As discussed with reference to FIG. 2, the control terminal 36 of the discharge transistor 35, e.g. gate electrode 136, is coupled to the drain domain 19 of the device 10 via a voltage divider 40. FIG. 5b shows an integration scheme for the voltage divider 40, namely a capacitor 140 coupling the gate electrode 136 of the discharge transistor 35 to the drain domain 19. The capacitor 40 is formed in an area of the die 100, which is electrically isolated from the discharge transistor 35 and from the device 10 via a respective deep trench isolation 340, 341. In a trench 146, a first capacitor electrode 145.1 is arranged, a second capacitor electrode 145.2 is formed in the surrounding portion of the semiconductor body 110. In between, a dielectric 149 of the capacitor 140 is disposed. The first capacitor electrode 145.1 extends deeper than the gate electrode of the device, for instance to the same depth like the field electrode of the device.

The second capacitor electrode 145.2 is contacted via a first deep contact structure 147.1, which may comprise a trench and implant structure, see in detail above. With a second deep contact structure 147.2, the drain potential is picked from the second side 110.2 of the semiconductor body 110, the deep contact structures 147.1, 147.2 connected to each other in the metallization layer 35. When the semiconductor device 10 is switched off and the backside potential rises, this can be sensed via the capacitor 140 to switch the discharge transistor 35 into the conducting state and discharge the field electrode 12.

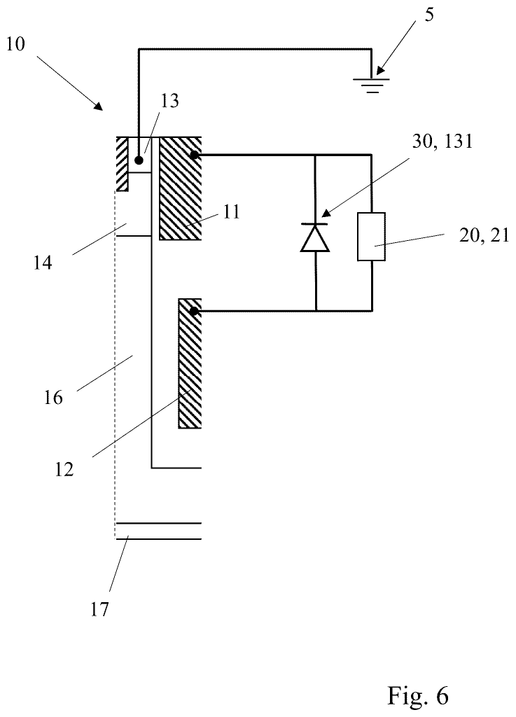

FIG. 6 illustrates another semiconductor circuit, again exemplified by the device 10 shown in FIG. 1. The delay element 20 is again a resistor 21, which delays a charging of the field electrode 12 to the gate potential. Instead of the discharge transistor, the discharge element 30 of FIG. 8 is a diode 131. It is connected in parallel to the resistor 21 and blocks a charging of the field electrode 12 from the gate electrode 11, but enables a discharging in the opposite direction.

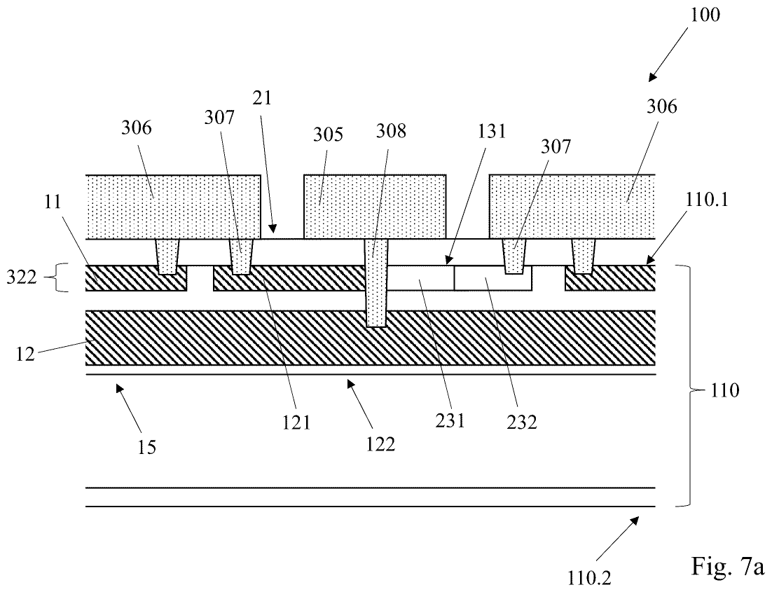

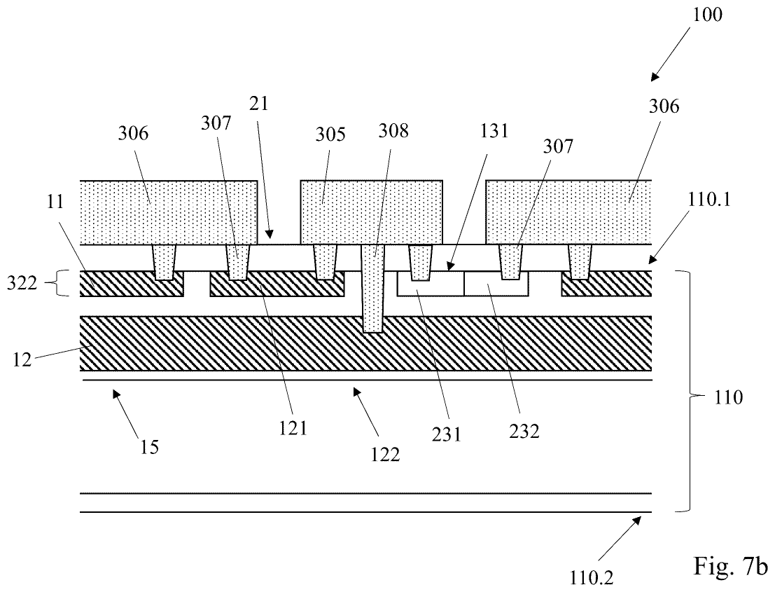

FIG. 7a illustrates a possible integration of the circuit 1 of FIG. 6. As in FIG. 3, a resistive element 121 of the resistor 21 is arranged in a trench 122, which is the field electrode trench 15 comprising the gate electrode 11 and field electrode 12 in another portion. Via the vertical interconnect 308 formed below the conductor line 305, the resistive element 121 is connected to the field electrode 12, wherein another vertical interconnect 307 provides for the connection to the gate potential, e.g. to a gate conductor line 306. In the same polysilicon layer 322, the diode 131 is formed. Manufacturing-wise, this may be realized with an additional mask defining an opening for a respective doping. Via the vertical interconnect 308, the diode, e.g. cathode contact 231 of the diode 131, is connected to the field electrode 12, another interconnect 307 provides for a connection of the anode contact 232 of the diode 131 to the gate potential.

FIG. 7b illustrates a slightly amended integration scheme compared to FIG. 7a. In this case, the vertical interconnect 308 connected to the field electrode 12 does not contact the resistive element 121 and the diode 131 directly, instead the contact is routed via the conductor line 305 above.

FIG. 8 shows another circuit 1 for the coupling of the gate electrode 11 and the field electrode 12. In this embodiment, the resistor 21 serving as delay element 20 is also used as discharge element 30, e.g. to discharge the field electrode 12 via the gate electrode 11 after the switching event. In addition, the field electrode 12 is coupled to the ground domain 5 via a capacitor 50, which may keep the field electrode potential low during switching events.

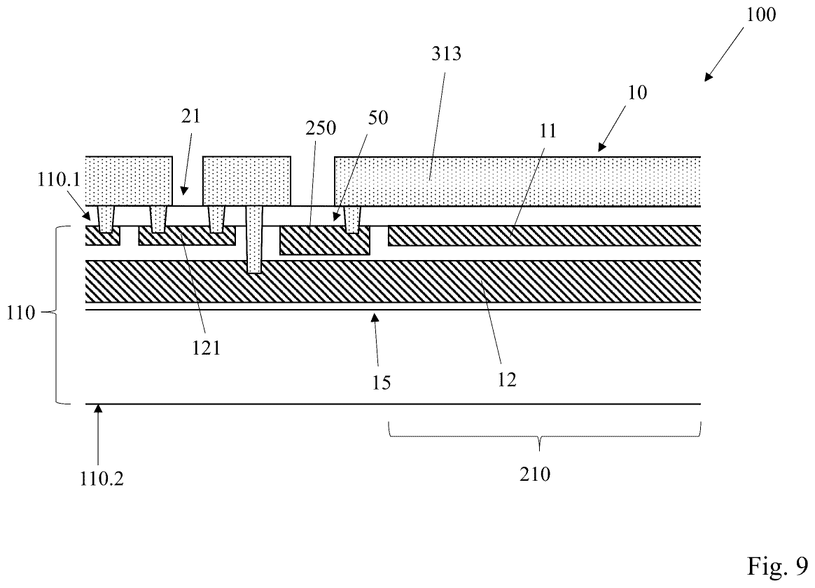

FIG. 9 shows an example for an integration of the circuit 1 of FIG. 8. As discussed in detail with reference to FIGS. 3 and 7, the resistive element 121 of the resistor 21 is arranged in the trench 122, namely is arranged in another portion of the field electrode trench 15 comprising the gate electrode 11 and field electrode 12. In the same trench 15, laterally between the resistive element 121 and the device 10 in the active area 210, the capacitor 50 is disposed. A capacitor electrode 250, which connects to a source plate 313, e.g. ground domain 5, is arranged above the field electrode 12. The other the capacitor electrode 251 is formed by the field electrode 12 itself, see also FIG. 8 for illustration.

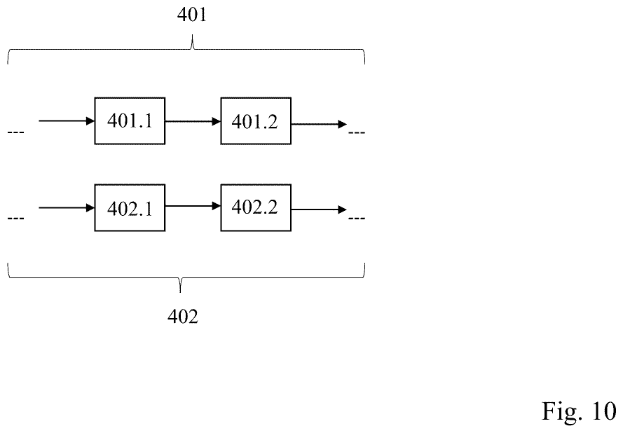

FIG. 10 summarizes some manufacturing steps. A forming 401 of the semiconductor device 10 and a forming 402 of the delay element 20 may take place at least partially simultaneously. The forming 401 of the semiconductor device 10 may for instance comprise an etching 401.1 of a trench and filling 401.2 of the trench, wherein the delay element 20, e.g. resistor 21, may be formed 402 in the same etching 402.1 and filling steps, see the remarks above.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor circuit, comprising:
a semiconductor device; and
a delay element;
wherein the semiconductor device comprises:
a gate electrode; and
a field electrode in a field electrode trench,
wherein the delay element is electrically connected between the gate electrode and the field electrode,
wherein the delay element is configured to delay a charging of the field electrode compared to a charging of the gate electrode.

2. The semiconductor circuit of claim 1, wherein the delay element is a resistor electrically connecting the field electrode to the gate electrode.

3. The semiconductor circuit of claim 1, further comprising:
a discharge element electrically connected between the field electrode and a ground domain,
wherein the discharge element is configured to discharge the field electrode when the gate electrode is discharged.

4. The semiconductor circuit of claim 3, wherein the discharge element is a discharge transistor.

5. The semiconductor circuit of claim 4, wherein a control terminal of the discharge transistor is coupled to a drain domain of the semiconductor device via a resistive and/or capacitive voltage divider.

6. The semiconductor circuit of claim 1, further comprising:
a capacitor electrically connected between the field electrode and a ground domain.

7. A semiconductor die, comprising:
a semiconductor body;
a wiring structure; and
the semiconductor circuit of claim 1,
wherein the gate electrode is arranged above the field electrode in the field electrode trench.

8. The semiconductor die of claim 7, wherein the semiconductor circuit further comprises a discharge transistor electrically connected between the field electrode and a ground domain, wherein the discharge transistor is configured to discharge the field electrode when the gate electrode is discharged, and wherein the discharge transistor and the semiconductor device are electrically isolated from each other by a deep trench isolation or junction isolation in the semiconductor body.

9. The semiconductor die of claim 7, wherein the semiconductor circuit further comprises a discharge transistor electrically connected between the field electrode and a ground domain, wherein the discharge transistor is configured to discharge the field electrode when the gate electrode is discharged, wherein the discharge transistor is a vertical device having a source region at a first side of the semiconductor body and a drain region at a vertically opposite second side of the semiconductor body, and wherein the field electrode is electrically connected to the drain region of the discharge transistor via a deep contact extending from the first side into the semiconductor body.

10. The semiconductor die of claim 7, wherein the semiconductor circuit further comprises a discharge transistor electrically connected between the field electrode and a ground domain, wherein the discharge transistor is configured to discharge the field electrode when the gate electrode is discharged, and wherein the discharge transistor and the semiconductor device are electrically isolated from each other by a deep trench isolation or junction isolation in the semiconductor body.

11. The semiconductor die of claim 7, wherein the semiconductor circuit further comprises a discharge transistor electrically connected between the field electrode and a ground domain, wherein the discharge transistor is configured to discharge the field electrode when the gate electrode is discharged, wherein the discharge transistor is a vertical device having a source region at a first side of the semiconductor body and a drain region at a vertically opposite second side of the semiconductor body, wherein the field electrode is electrically connected to the drain region of the discharge transistor via a deep contact extending from the first side into the semiconductor body, wherein the discharge transistor and the semiconductor device are electrically isolated from each other by a deep trench isolation or junction isolation in the semiconductor body, and wherein the wiring structure comprises a conductor line which extends across the deep trench isolation or junction isolation and electrically connects the deep contact to the field electrode.

12. The semiconductor die of claim 7, wherein the semiconductor circuit further comprises a discharge transistor electrically connected between the field electrode and the ground domain, wherein the discharge transistor is configured to discharge the field electrode when the gate electrode is discharged, wherein a control terminal of the discharge transistor is capacitively coupled to a drain domain of the semiconductor device via a first capacitor electrode arranged in a trench and/or via a second capacitor electrode formed in the semiconductor body and connected to the drain domain of the semiconductor device via a deep contact.

13. The semiconductor die of claim 7, wherein the delay element is a resistor electrically connecting the field electrode to the gate electrode, and wherein the resistor comprises a resistive element made of polysilicon in a trench.

14. The semiconductor die of claim 13, wherein the resistor comprises a same polysilicon layer as the gate electrode of the semiconductor device.

15. The semiconductor die of claim 7, wherein the semiconductor circuit further comprises a capacitor electrically connected between the field electrode and a ground domain, and wherein a capacitor electrode of the capacitor is connected to the ground domain and arranged above the field electrode in the field electrode trench.

16. The semiconductor die of claim 7, wherein the semiconductor circuit further comprises a discharge element electrically connected between the field electrode and the ground domain, wherein the discharge element is configured to discharge the field electrode when the gate electrode is discharged, and wherein the discharge element is a diode made of polysilicon in a trench.

17. The semiconductor die of claim 16, wherein the diode is made of a same polysilicon layer as the gate electrode of the semiconductor device.

18. A method of manufacturing a semiconductor die, the method comprising:
forming a semiconductor device, wherein the semiconductor device comprises a gate electrode and a field electrode in a field electrode trench; and
forming a delay element, wherein the delay element is electrically connected between the gate electrode and the field electrode, wherein the delay element is configured to delay a charging of the field electrode compared to a charging of the gate electrode.

19. A semiconductor device, comprising:
gate electrode;
a field electrode disposed in a trench;
a resistor electrically connected between the gate electrode and the field electrode; and
a discharge element electrically connected between the field electrode and a ground domain,
wherein the discharge element is one of a discharge transistor, a diode, and a capacitor.
